(19) United States
(12) Patent Application Publication
(10) Pub. No.: US 2016/0025781 A1
(43) Pub. Date: Jan. 28, 2016

(54) HOUSING ALLOCATION DEVICE AND METHOD FOR ALLOCATING HOUSING

(71) Applicant: FUJITSU LIMITED, Kawasaki-shi (JP)

(72) Inventors: Tomoyuki Kumeta, Shiroi (JP); Keita Murakami, Kawasaki (JP)

(73) Assignee: Fujitsu Limited, Kawasaki (JP)

(21) Appl. No.: 14/751,644

(22) Filed: Jun. 26, 2015

(30) Foreign Application Priority Data
Jul. 25, 2014 (JP) 2014-151755

(51) Int. Cl. G01R 21/00; H05K 7/14; H05K 7/20

(52) U.S. Cl. CPC G01R 21/00; H05K 7/2059; H05K 7/1488; H05K 7/1497

(57) ABSTRACT

A housing allocation device includes a processor. The processor is configured to obtain respective power consumption values of a plurality of housings installed in a room. The processor is configured to determine, on basis of the obtained power consumption values, first housings each have a power consumption value larger than a predetermined value. The processor is configured to select, as mounting destination candidates for a mounting destination of a first electronic apparatus to be installed in the room, second housings each of which accommodates the first electronic apparatus and faces none of the first housings from the plurality of housings on basis of arrangement information indicating arrangement of the plurality of housings in the room. The processor is configured to output information regarding at least one of the mounting destination candidates.

### CROSS-REFERENCE TO RELATED APPLICATION

This application is based upon and claims the benefit of priority of the prior Japanese Patent Application No. 2014-151755, filed on Jul. 25, 2014, the entire contents of which are incorporated herein by reference.

### FIELD

The embodiments discussed herein are related to a housing allocation device and a method for allocating a housing.

### BACKGROUND

In a data center, when accommodating a system (electronic instrument such as server, or network device) of a user, there is a case in which an operator in the data center, for example, a person in charge of layout, performs an allocation of a rack in the center so that an optimal rack in a server room (computer room) is provided to the user. As a material (parameter) for determining a rack to be provided to the user, there is a power consumption value and a heat value of an allocated rack, a cooling capability of an air conditioner in the server room, a presence or absence of continuous (neighboring) empty racks, the number of empty breakers of a distribution board, and the like.

A technology has been known in which cooling efficiency in the data center is further improved by arranging a high heat generation rack device at a location which is closer to the air conditioner in the data center.

A related technique is disclosed in, for example, Japanese Laid-open Patent Publication No. 2011-59741.

In many cases, the determination (selection) of a rack to be allocated to a system (user system) of a user is manually performed by an operator. At this time, the operator grasps and manages a use state (power consumption value, or the like) of a rack which is being provided to a user, information on an empty rack, or the like. Using the information (parameter) the operator may determine a rack to be allocated to a new user system.

The user is able to arbitrarily increase or decrease the number of electronic instruments (electronic apparatuses) mounted on the allocated rack. Normally, the operator is informed of the fact of increasing or decreasing the number of electronic instruments; however, there is a case in which the operator is not informed of the fact, or the fact is omitted in managing on the operator side even when the operator is informed. In this case, the operator may not grasp the exact number of electronic instruments which is mounted on the rack, and uses a parameter (for example, power consumption value, or the like) which is different (wrong) from a present situation when determining a rack to be allocated to a system.

For example, a case in which an operator does not recognize that the number of electronic instruments on a certain rack is increased will be assumed. In this case, the operator misrecognizes that a power consumption value (heat value) of the certain rack is smaller than an actual value, and allocates an empty rack in the vicinity of the certain rack to a new user system. However, since the actual power consumption value of the certain rack is greater than the value which is recognized by the operator, there is a case in which the rack which is allocated to the new user system, or the certain rack is not sufficiently cooled.

Thus, when the operator in the data center does not recognize the latest state of a rack, a rack which is determined based on a parameter different from a present situation is allocated to the new user system, and there is a concern that a disorder may be caused in cooling, or the like, of the rack.

### SUMMARY

According to an aspect of the present invention, provided is a housing allocation device including a processor. The processor is configured to obtain respective power consumption values of a plurality of housings installed in a room. The processor is configured to determine, on basis of the obtained power consumption values, first housings each have a power consumption value larger than a predetermined value. The processor is configured to select, as mounting destination candidates for a mounting destination of a first electronic apparatus to be installed in the room, second housings each of which accommodates the first electronic apparatus and faces none of the first housings from the plurality of housings on basis of arrangement information indicating arrangement of the plurality of housings in the room. The processor is configured to output information regarding at least one of the mounting destination candidates.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram which illustrates an exemplary configuration of a data center according to a first embodiment;

FIG. 2 is a diagram which illustrates an exemplary plan view of a server room which is illustrated in FIG. 1;

FIG. 3 is a diagram which illustrates an exemplary cross-sectional view which is taken along arrow III-III in FIG. 2;

FIG. 4 is a diagram which illustrates an exemplary cross-sectional view which is taken along arrow IV-IV in FIG. 2;

FIG. 5 is a diagram which illustrates an exemplary functional configuration of a managing unit which is illustrated in FIG. 1;

FIG. 6 is a diagram which illustrates an example in which a server room illustrated in FIG. 1 is simplified;

FIG. 7 is a diagram which illustrates an example of an underfloor space value table which is illustrated in FIG. 5;

FIG. 8 is a diagram which illustrates an example of a power supply line adding table which is illustrated in FIG. 5;

FIG. 9 is a diagram which illustrates an example of a layout table which is illustrated in FIG. 5;

FIG. 10 is a diagram which illustrates an exemplary application of an allocation process performed by a managing unit which is illustrated in FIG. 5;

FIG. 11 is a flowchart which illustrates an example of an allocation process for a new rack performed by a managing unit which is illustrated in FIG. 5;

FIG. 12 is a flowchart which illustrates an example of an allocation process for a new rack performed by a managing unit which is illustrated in FIG. 5;

FIG. 13 is a flowchart which illustrates an example of an allocation process for a new rack performed by a managing unit which is illustrated in FIG. 5;

FIG. 14 is a flowchart which illustrates an example of an updating process performed by a managing unit which is illustrated in FIG. 5 after increasing an electronic instrument;

FIG. 15 is a flowchart which illustrates an example of an updating process performed by a managing unit which is illustrated in FIG. 5 after removing an electronic instrument;

FIG. 16 is a flowchart which illustrates an example of an updating process performed by a managing unit which is illustrated in FIG. 5 after completion of service; and

FIG. 17 is a diagram which illustrates an exemplary hardware configuration of a managing unit which is illustrated in FIG. 5.

### DESCRIPTION OF EMBODIMENTS

Hereinafter, embodiments will be described with reference to drawings. The embodiments described below are merely examples, and there is no intention of excluding various modifications, or an application of a technology which is not expressed below. That is, the embodiments may be executed by performing various modifications without departing from the scope thereof. In the following embodiments, portions which are given similar reference numerals in drawings denote similar portions unless stated otherwise, particularly.

In a data center, as described above, when an empty rack is allocated to a new user system, in many cases, an allocation work dependent on individual skills is performed by a manual work of an operator in the data center, for example, a person in charge of layout.

Air (cold air) which is sent out from an air conditioner is taken in by an electronic instrument (electronic apparatus) which is mounted on a server rack, for example, from the front face. For this reason, when front faces of racks (electronic instruments) on which electronic instruments with a high load are mounted are caused to face each other, intake faces of electronic instruments on each rack face each other, and accordingly, an amount of cold air which is taken in by each electronic instrument is reduced, and cooling efficiency for the electronic instruments deteriorates.

Therefore, in order to supply cold air to a rack with a high load in a preferential manner, it may be taken into consideration that a rack (on opposite side) which faces the high load rack is set to be a rack which is not to be allocated, that is, even when the rack is an empty rack, the rack which faces the high load rack is not to be allocated. In order to grasp which rack is a high load rack, an operator may use information on a use state (power consumption value, or the like) of a rack which is being provided to a user, information on an empty rack, or the like. However, as described above, there is a case in which a rack which is a low load rack when receiving a system is changed to a high load rack due to an enlargement of devices without the operator's knowledge, or the fact is omitted in managing even when the operator is informed of the enlargement of devices from a user.

It may also be taken into consideration that, when determining a rack to be allocated to a new user system, an operator grasps a current load state of a rack, by checking the number of electronic instruments which are mounted on the rack which is an allocation candidate (mounting destination candidate). However, since there is a cover on the front face of the rack in many cases, it may be difficult for the operator to perform visual checking.

### First Embodiment

In contrast to this, in a data center according to a first embodiment which will be described below, a managing unit (output unit) may obtain respective power consumption with respect to a plurality of racks (housing) which may be mounted with electronic instruments (electronic apparatuses), and are provided in a server room (computer room). The managing unit may determine a rack which does not face a rack of which power consumption is larger than a predetermined value, as a housing of a mounting destination candidate on which a new electronic instrument is mounted, based on the obtained power consumption of the plurality of racks and arrangement information of a plurality of housings in the computer room.

In this manner, an allocation work for a rack, which is presently dependent on individual skills as performed by a manual work of an operator in the data center, may be performed by the managing unit without depending on individual skills, and it is possible to reduce omission in managing by the operator with respect to updated information regarding a rack. In addition, also in a case in which the operator does not recognize the fact that an enlargement of devices is performed with respect to an existing rack, and the rack becomes a high load rack, it is possible for the managing unit to easily identify a high load rack on the basis of power consumption which is obtained from each rack, and to exclude a rack facing the high load rack from allocation candidate racks.

As described above, in the managing unit according to the present embodiment, it is possible to determine a rack, in the server room, as an appropriate mounting destination candidate on which a new electronic instrument is to be mounted. Hereinafter, the data center according to the present embodiment will be described in detail.

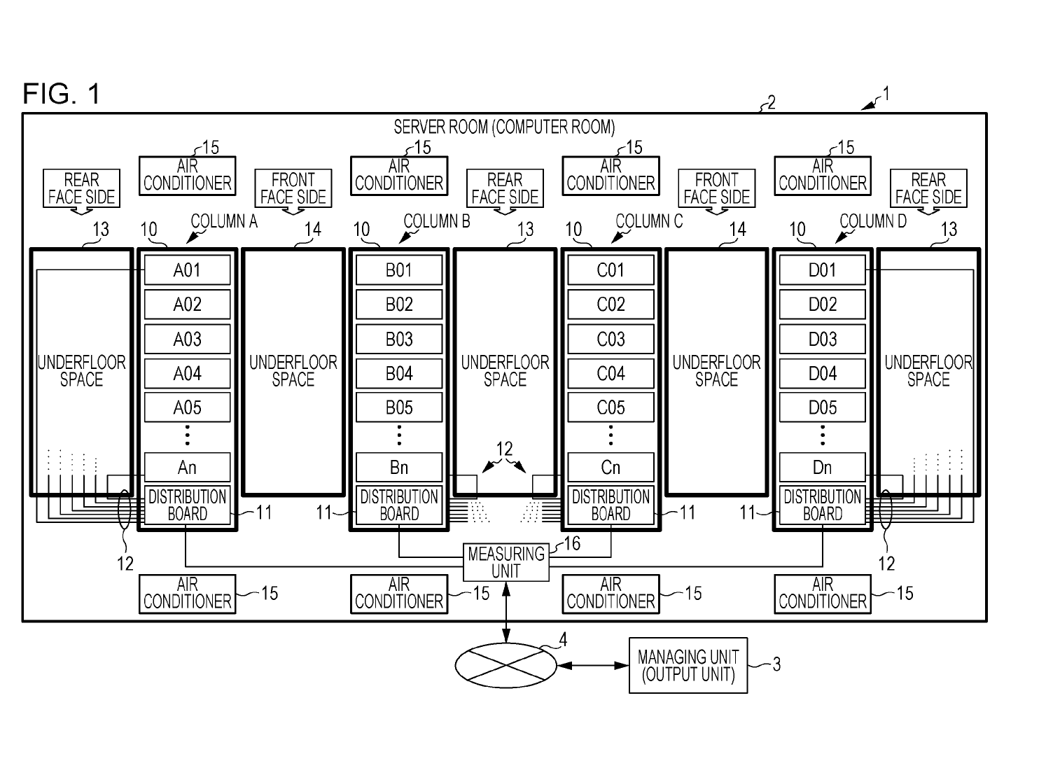

FIG. 1 is a diagram which illustrates an exemplary configuration of a data center 1 according to the present embodiment. The data center 1 according to the present embodiment includes a server room (computer room) 2, and a managing unit 3. A plurality of columns which include a plurality of (for example, n; n is an integer of 2 or more) racks 10, and one or more (for example, one) distribution boards 11, for example, are arranged in the server room 2. In the example illustrated in FIG. 1, spaces of four columns (column A to column D) are secured in the server room 2, and the distribution board 11 is provided in each column. It is possible to provide n servers 10 at the maximum in each column. The server room 2 may include underfloor spaces 13 and 14, air conditioners 15, and a measuring unit 16.

The server room 2 may be one room which is provided in the above described data center 1, or may be a data center of a container type of a modular type.

Hereinafter, when specifically describing a individual rack 10 in each column, the racks are denoted by racks A01 to An, B01 to Bn, C01 to Cn, and D01 to Dn, using rack names which are attached to the racks 10 illustrated in FIG. 1.

The rack 10 is an example of a housing on which a plurality of electronic instruments (electronic apparatuses) 10a (refer to FIG. 4) are mounted. As the rack 10, there is a general server rack. It is preferable that the electronic instrument 10a has an air flow in which air is taken in from the front face and is exhausted to the rear face and is mounted on the rack 10 such that the front face of the electronic instrument 10a is placed at the front face side of the rack 10 and the rear face is placed at the rear face side of the rack 10.

As the electronic instrument 10a which may be mounted on the rack 10, there is, for example, an information processing device such as a server (for example, rack-mounted server), a storage device in which a plurality of storage units may be mounted, and various network devices such as a network switch, a router, or the like. As another example of the electronic instrument 10a, there is a power supply device such as an uninterruptible power supply (UPS), a console, or the like.

In the server room 2 according to the present embodiment, each rack 10 is arranged so as to face a rack 10 in a neighboring column with each other either on the front faces or on the rear faces. For example, in the example illustrated in FIG. 1, the racks A01 to An in column A are arranged so that respective front faces face the column B side, and the racks B01 to Bn in column B are arranged so that respective front faces face the column A side. Similarly, the rack C01 to Cn in column C are arranged so that respective front faces face the column D side, and the racks D01 to Dn in column D are arranged so that respective front faces face the column C side.

The distribution board 11 is a unit which distributes a power supply to each rack 10 from a power supply (main power supply) of the data center 1 (server room 2), and may supply power to the rack 10 through a power supply line (power supply cable) 12. The number of systems (for example, number of breakers, or number of power supply lines 12) of the power supply is predetermined, and becomes n to n+m (m is an integer of 1 or more) systems with respect to one distribution board 11, for example.

In consideration of a power loss, or the like, a cable with a large diameter is used as the power supply line 12 when a distance between the distribution board 11 and the rack 10 is long. The distribution board 11 basically distributes a power supply to the racks 10 in the column in which the distribution board 11 is provided. However, when another distribution board 11 may not distribute a power supply any more (for example, there is no empty breaker), the distribution board 11 also may distribute a power supply to a rack 10 in a column in which the another distribution board 11 is provided.

The spaces 13 and 14 for wiring under the floor are provided between columns in the server room 2. In the example illustrated in FIG. 1, the underfloor space 13 is provided at underfloor on the rear face side (between wall and column A, between column B and column C, between column D and wall) of each column, and the underfloor space 14 is provided at underfloor on the front face side (between column A and column B, and between column C and column D) of each column.

The underfloor space 13 is a space in which the power supply line 12 with respect to each rack 10 of a neighboring column is laid from the distribution board 11 of the neighboring column, and through which cooling air passes. That is, the underfloor space 13 is an example of one or more ventilation spaces which are provided corresponding to each of a plurality of columns which are formed in the server room 2 by the plurality of racks 10, through which cooling air which cools the racks 10 which form a column passes, and in which cables (power supply lines 12) connected to the racks 10 which forms the column are laid. In the example illustrated in FIG. 1, only a part of the power supply lines 12 is illustrated, and illustrations of other power supply lines 12 are omitted in order to simplify the drawing.

The underfloor space 14 is a space in which a communication cable for connecting each rack 10 in a neighboring column and a network (not illustrated, for example, network device which is connected to the Internet or intranet) is laid. Cooling air which cools the racks 10 forming a column may also pass through the underfloor space 14, and the underfloor space 14 is also an example of the ventilation space. In the example illustrated in FIG. 1, the communication cable is not illustrated in order to simplify the drawing. As the communication cable, for example, there are various cables such as a local area network (LAN) cable, or an optical fiber cable.

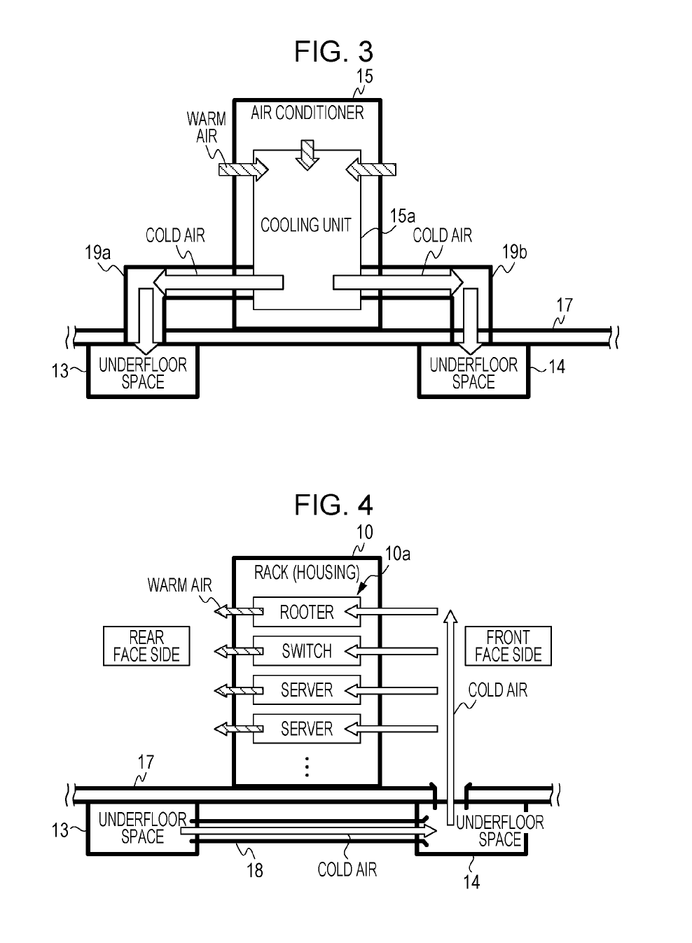

The air conditioner 15 is an air conditioning system for cooling the server room 2, and in particular, the racks 10. In FIG. 1, two air conditioners in each column, and eight air conditioners in total are installed in the server room 2. The air conditioner 15 according to the present embodiment cools each rack 10, takes in air (warm air) which is warmed by the rack 10, cools the warm air which is taken in using a cooling unit 15a (refer to FIG. 3), and exhausts the cooled air (cold air).

The measuring unit 16 obtains a power consumption value (VA) from each distribution board 11. For example, the measuring unit 16 may measure values of a current and a voltage in each system of the distribution board 11 using a probe or the like, and obtain a power consumption value. The measuring unit 16 may be provided for each distribution board 11, or one measuring unit may be provided for the plurality of distribution boards 11 as illustrated in FIG. 1. The measuring unit 16 may be accommodated under the floor 17 (refer to FIG. 3), or may be mounted on any of rack 10 in the server room 2.

The managing unit (output unit) 3 is a unit which performs an allocation process in which racks 10 are determined as appropriate mounting destination candidates on which a new electronic instrument 10a is to be mounted and one or more racks 10 are allocated to a user system from among the racks 10 determined as the mounting destination candidates. The managing unit 3 collects a power consumption value which is measured by the measuring unit 16 of the server room 2 through the network 4 such as the Internet, or the intranet in the data center, and uses the power consumption value in the allocation process.

The mounting destination candidate rack 10 may be an empty rack 10 itself, or may be an installation space of the rack 10. Accordingly, allocation of the rack 10 to a user system may be allocation (lending) of the empty rack 10 itself to a user, or may be allocation (lending) of the installation space of the rack 10 to the user.

In the example illustrated in FIG. 1, the managing unit 3 is provided at the outside of the server room 2, for example, in a control room or the like of the data center 1. However, there is no limitation to this. The managing unit 3 may be provided inside the server room 2 (under the floor 17 (refer to FIG. 3) or the rack 10), for example. In this case, an operator may access the managing unit 3 in the server room 2 from the control room or the like, through the network 4 or the like. As the managing unit 3, there is an information processing device (computer) such as a server, or a personal computer (PC).

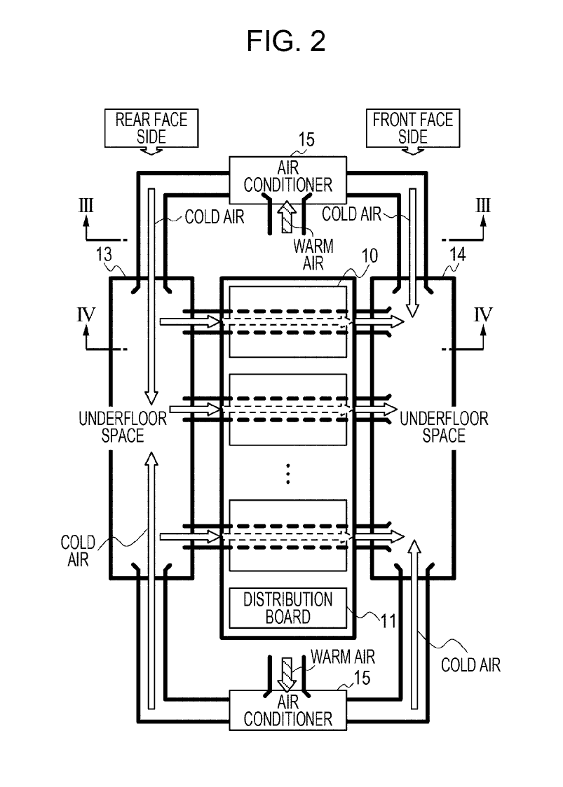

Subsequently, an example of a cooling method for the rack 10 in the server room 2 according to the present embodiment will be described. In the server room 2 according to the present embodiment, as illustrated in FIGS. 2 to 4, cold air from the air conditioner 15 is supplied to the rack 10 through the underfloor spaces 13 and 14. FIG. 2 illustrates an exemplary plan view of the server room 2, FIG. 3 illustrates an exemplary cross-sectional view which is taken along arrow III-III in FIG. 2, and FIG. 4 illustrates an exemplary cross-sectional view which is taken along arrow IV-IV in FIG. 2.

As illustrated in FIG. 3, warm air which is taken in from the upper part of the air conditioner 15 is cooled by the cooling unit 15a which includes a heat exchanger or the like, and is sent to ducts 19a and 19b as cold air from the lower part of the cooling unit 15a. The duct 19a is connected to the underfloor space 13 through an opening which is provided in the floor 17 of the server room 2, and the duct 19b is connected to the underfloor space 14 through an opening which is provided in the floor 17 of the server room 2. As illustrated in FIG. 2, the cold air which passes through the duct 19a flows into the underfloor space 13 through the opening, and passes through the inside of the underfloor space 13 in parallel, or approximately in parallel to a column of the racks 10 or the power supply lines 12. The cold air which passes through the duct 19b flows into the underfloor space 14 through the opening, and passes through the inside of the underfloor space 14 in parallel, or approximately in parallel to a column of the racks 10 or the communication cables.

As illustrated in FIG. 4, the cold air which passes through the inside of the underfloor space 13 passes through a duct 18 which is laid so as to be perpendicular, or approximately perpendicular to the column of the racks 10 under (underfloor) each rack 10, and communicates with the underfloor space 13 and the underfloor space 14 (refer to FIG. 2). The cold air which passes through the duct 18 flows into the underfloor space 14, and is blown up at the front face side of each rack 10 through the opening which is provided in the floor 17. The cold air which passes through the duct 18 may not flow into the underfloor space 14, and may be blown up from an opening which is provided in the floor 17 between the underfloor space 14 and the column of the racks 10, for example. Cold air which passes through the underfloor space 14 via the duct 19b joins the cold air which passes through the duct 18 in the underfloor space 14, and is blown up at the front face side of each rack 10 from the underfloor space 14 through the opening which is provided in the floor 17.

The cold air which is blown up at the front face side of each rack 10 is taken in from the front face side of respective electronic instruments 10a in each rack 10, as illustrated in FIG. 4, and is exhausted to the rear face side of the respective electronic instruments 10a, that is, to the rear face side of each rack 10 as warm air. The warm air which is exhausted from each rack 10 is taken in from the upper part of the air conditioner 15, as described above (refer to FIG. 3).

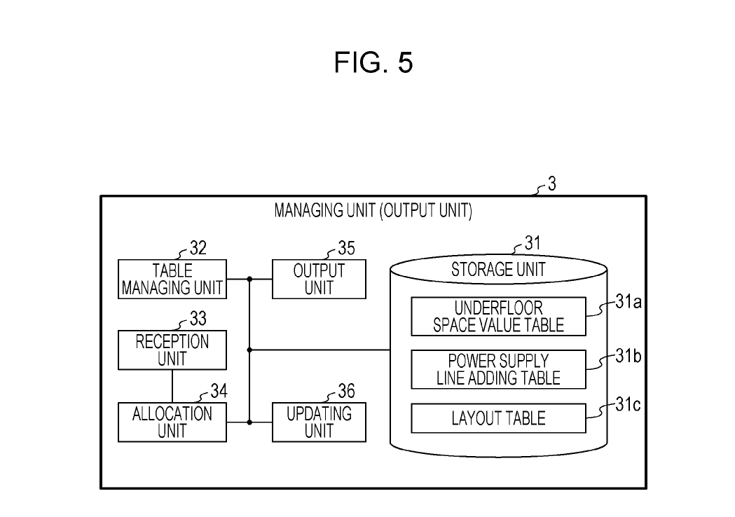

Subsequently, an exemplary configuration of the managing unit 3 according to the present embodiment will be described with reference to FIGS. 5 to 9. As illustrated in FIG. 5, the managing unit 3 includes a storage unit 31, a table managing unit 32, a reception unit 33, an allocation unit 34, an output unit 35, and an updating unit 36.

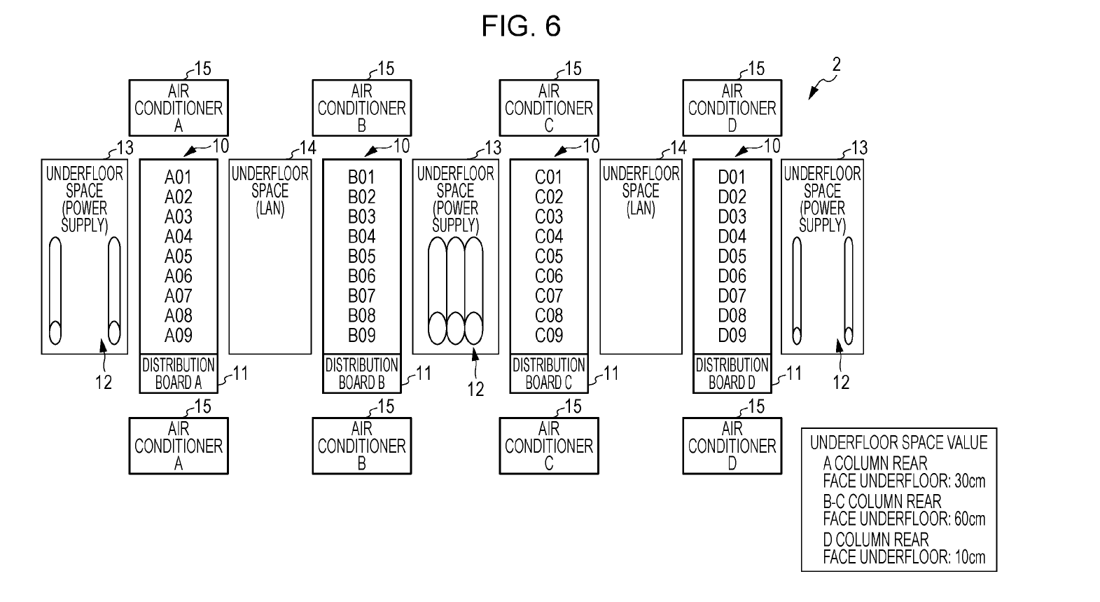

In the following description, columns A to D are secured in the server room 2 as spaces for installing the rack 10, and an operator determines a space (position) for installing a rack 10 (user rack) of a user through the managing unit 3 in response to an installation request for the rack 10 from the user. In the following description, FIG. 6 which illustrates a simplified server room 2 is used. Regarding FIG. 6, there is a case in which the distribution boards 11 and the air conditioners 15 corresponding to columns A to D are denoted by distribution boards A to D, and air conditioners A to D, respectively.

The storage unit 31 is a storage region in which various information which is used by the managing unit 3 is stored, and is realized using a storage unit such as a memory which is included in the managing unit 3, a hard disk drive (HDD), a solid state drive (SSD), or an auxiliary storage unit such as a flash memory. The storage unit 31 stores (holds) an underfloor space value table 31a, a power supply line adding table 31b, and a layout table 31c.

The table managing unit 32 manages the underfloor space value table 31a, the power supply line adding table 31b, and the layout table 31c which are stored in the storage unit 31.

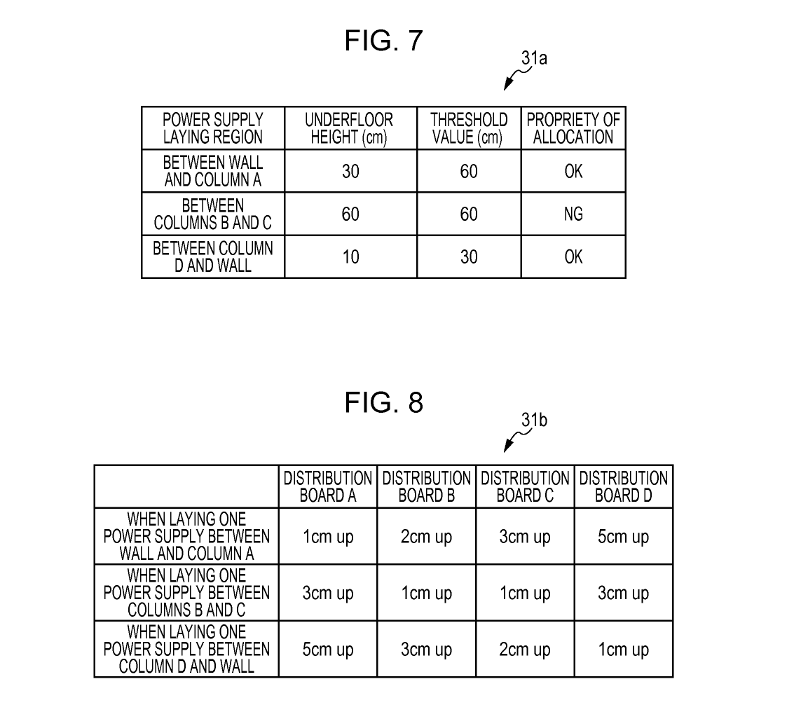

The underfloor space value table 31a is a table in which a space value (underfloor space value) denoting a space which is occupied by the cables (power supply lines 12) in the underfloor space 13 is managed. As the underfloor space value, there is a height (underfloor height) of the power supply lines 12 which are laid in the underfloor space 13. In the underfloor space value table 31a, as illustrated in FIG. 7, items of “power supply laying region” which denotes a position of the underfloor space 13, “underfloor height” (cm) of the underfloor space 13, “threshold value” (cm) which is set in each underfloor space 13, and “propriety of allocation” are included.

The “threshold value” is a value which denotes a space (for example, height) which is occupied by the power supply lines 12 in the underfloor space 13 in which a minimum space (for example, height), which is to be secured in the underfloor space 13 in order for the air conditioner 15 to sufficiently exerts an ability of underfloor air conditioning, is excluded. The “propriety of allocation” is information which denotes whether or not to allocate a rack 10 in a column for which the underfloor space 13 is used when laying the power supply line 12. A rack 10 in a column for which the underfloor space 13 is used is not allowed to be allocated with respect to the underfloor space 13 in which “NG” is set, for example.

The table managing unit 32 updates the underfloor space value table 31a every time the underfloor space value of the underfloor space 13 is changed.

A diameter of the power supply line 12 becomes different according to a distance between an allocated rack 10 and the distribution board 11, as follows:

distance between distribution board and rack (greater than 0 m and equal to or less than 5 m): cable diameter (3 cm);

distance between distribution board and rack (greater than 5 m and equal to or less than 10 m): cable diameter (5 cm);

distance between distribution board and rack (greater than 10 m): cable diameter (7 cm).

For example, as illustrated in FIG. 6, in the underfloor space 13 between column B and column C, the power supply line 12 is in a congested state, since diameters of the power supply lines 12 are larger, or/and the number of lines is larger compared to the underfloor space between wall and column A, and between column D and wall. In FIG. 6, a thickness of the power supply cable becomes large between column B and column C, between wall and column A, and column D and wall in order. When many thick cables are piled in the underfloor space 13 like the state between column B and column C, there is a concern that underfloor air conditioning may not function since a flow of cold air is blocked by the power supply cables.

In a case in which a rack 10 is installed in a new floor, or the like, of the data center 1, it is possible to install the rack 10 in order from an end of the floor. However, when a rack 10 is arranged in an empty area, or the like, due to removal of a rack 10, or the like, there is a case in which management of the underfloor space 13 is dependent on individual skills of operators.

Therefore, when the “underfloor height” is the “threshold value” or more, that is, when it is not possible to secure a space of a predetermined value or more, the table managing unit 32 sets a rack 10 in the column to a non-allocable rack with respect to the underfloor space 13, in order to avoid any more laying of the power supply line 12. For example, as illustrated in FIG. 7, the “underfloor height” between column B and column C is 60 cm which is the same as the predetermined “threshold value” (60 cm), that is, the “underfloor height” is the “threshold value” or more. Accordingly, the table managing unit 32 sets the “propriety of allocation” in the underfloor space value table 31a for between column B and column C to “NG”, to make the racks 10 in column B and column C to be non-allocable racks.

In the example illustrated in FIG. 7, the “underfloor height” between wall and column A is 30 cm which is lower than the “threshold value” (60 cm), and the “underfloor height” between column D and wall is 10 cm which is lower than the “threshold value” (30 cm). Accordingly, the table managing unit 32 sets the “propriety of allocation” in the underfloor space value table 31a for between wall and column A, and for between column D and wall to “OK”, to make the racks 10 in column A and column D to be allocable racks. That is, the table managing unit 32 makes a rack 10 which is connected to a cable (power supply line 12) which is laid in an underfloor space 13 of which the “underfloor height” is less than the predetermined “threshold value” to be an allocation candidate (allocable rack).

The power supply line adding table 31b is a table which denotes an additional value which is added to the “underfloor height” in the underfloor space value table 31a when laying the power supply line 12, and is set in advance by an operator, or the like. Additional value is a value corresponding to a distance between a rack 10 to be allocated and a distribution board 11 which supplies power to the rack 10. The table managing unit 32 obtains a value which is added to the “underfloor height” with reference to the power supply line adding table 31b when updating the underfloor space value table 31a.

As illustrated in FIG. 8, an additional value when laying one power supply line 12 in the underfloor space 13 is set in each supply source of the power supply (distribution boards A to D (refer to FIG. 6)), in the power supply line adding table 31b. For example, the additional value becomes 1 cm when the one power supply line 12 which is laid in the rack 10 between wall and column A is a power supply line from the distribution board A, and becomes 2 cm, 3 cm, and 5 cm, respectively, when being power supply lines from the distribution boards B, C, and D.

As described above, a cable diameter of the power supply line 12 becomes different according to a distance between a distribution board and a rack. For example, in the example illustrated in FIG. 6, a distance between the distribution board C and the rack A01 is longer than a distance between the distribution board C and the rack A09. Therefore, the table managing unit 32 may determine an additional value which is added to the underfloor space value table 31a, in consideration of the distance between the distribution board and the rack instead of, or in addition to referring to the power supply line adding table 31b.

However, there also is a case in which the height or an area of the power supply line 12 in the underfloor space 13 does not increase, or increases by a value less than a diameter or the area of the power supply cable, even when the power supply line 12 is laid. For example, in the example illustrated in FIG. 6, even when the power supply line 12 is laid between wall and column A, there is a gap between two power supply cables, and the power supply line may be laid in the gap (there is space in width of underfloor space 13), there is almost no increase in “underfloor height” in the underfloor space 13 (substantial height or area of power supply line 12). Accordingly, when considering the distance between the distribution board and the rack, it is preferable that the table managing unit 32 sets, to an additional value, a value less than a diameter or an area (for example, cross-sectional area, or the like) of a power supply cable which is laid.

The layout table 31c is a table which denotes information on a layout of the plurality of racks 10 in the server room 2 (arrangement information), obtained power consumption values of the plurality of racks 10, and the “propriety of allocation” of the plurality of racks 10, or the like. The layout table 31c is a table which is used in allocation processing (which will be described later) performed by the allocation unit 34, and is updated by the table managing unit 32 in response to an instruction from the allocation unit 34 and the updating unit 36.

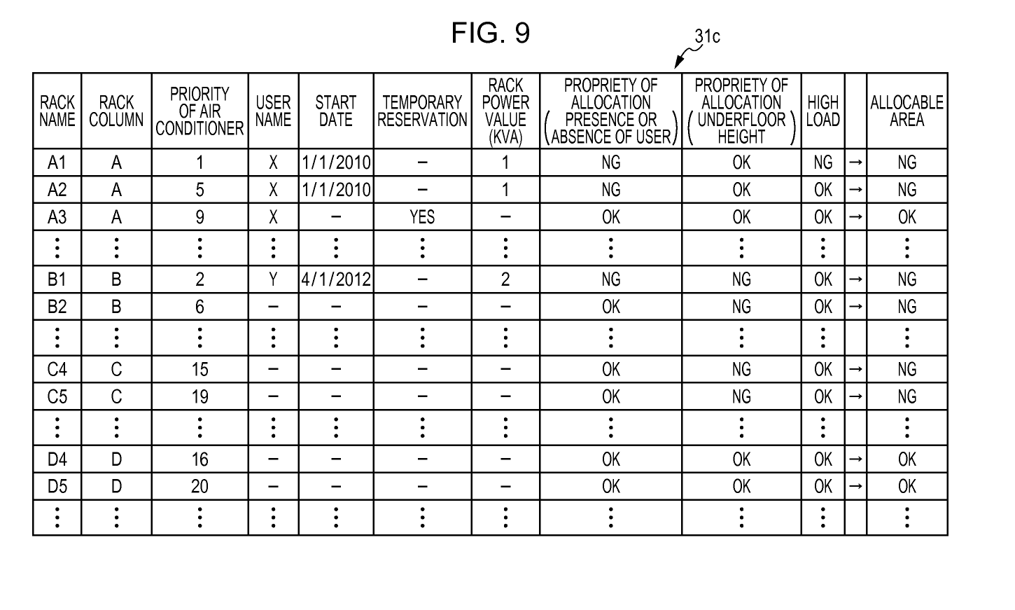

As illustrated in FIG. 9, in the layout table 31c, items of “rack name”, “rack column”, “priority of air conditioner”, “user name”, “start date”, “temporary reservation”, “rack power value (KVA)”, “propriety of allocation (presence or absence of user)”, “propriety of allocation (underfloor height)”, “high load” (whether or not it is in a high load circumstance), and “allocable area” (whether or not it is in an allocable area) are set.

In the “priority of air conditioner”, ascending numbers are allocated from a position of the rack 10 which is closer to the air conditioner 15, and the racks 10 in the same distance from the air conditioner 15 are allocated with numbers in order of a column which comes first. In the “temporary reservation”, “YES” is set to an empty rack 10 which is temporarily reserved. In the “rack power value (KVA)”, a power consumption value which is obtained through the measuring unit 16 is set.

In the “propriety of allocation (presence or absence of user)”, “OK” is set when the rack 10 is allocated to a user, and “NG” is set when the rack is not allocated to a user. In the “propriety of allocation (underfloor height)”, “OK” is set when the “propriety of allocation” in the underfloor space value table 31a is allocable (“OK”), and “NG” is set when the “propriety of allocation” is non-allocable (“NG”) by the table managing unit 32.

In the “high load”, “NG” is set when a rack 10 to be faced on the front face is a high load rack, and “OK” is set when the rack 10 is not a high load rack. Whether or not the rack 10 to be faced on the front face is a high load rack is determined by the allocation unit 34 or the updating unit 36 on the basis of a predetermined threshold value, for example. In the “allocable area”, “NG” is set when at least one of three conditions of the “propriety of allocation (presence or absence of user)”, the “propriety of allocation (underfloor height)” and the “high load” is “NG”, and “OK” which denotes an allocable state is set when all of the three conditions are “OK”.

The reception unit 33 receives, from an operator, an allocation request for a rack 10 with respect to a user. The number of racks to be allocated to a user and installation specifications are included in the allocation request. The installation specifications may include a size of the rack 10 to be installed, the number of power supply circuits, or power to be used (for example, a power value (KVA)), for example, and may include the number of electronic instruments 10a to be installed, a size thereof, and power to be used (for example, power value). When there are a plurality of racks 10 to be allocated to a user, the allocation request may include information denoting whether or not it is good to allocate a plurality of empty racks 10 (empty spaces) by distributing (whether or not it is possible to perform dispersion installation).

When an operator inputs the allocation request through an input unit which is included in the managing unit 3, the reception unit 33 calculates (obtains) allocation information including the number of racks, a power value of each rack 10, information denoting whether or not it is possible to perform dispersion installation (when the information is present) from the allocation request, and delivers the information to the allocation unit 34.

The allocation unit 34 performs an allocation process on the basis of the allocation information which is input from the reception unit 33. As an example, the allocation process is performed in the following procedure by the allocation unit 34. The procedure for performing the allocation process is not limited to the following procedure, and the allocation process may be performed in random order. At least one operation of the following procedure may be omitted in the allocation process.

(1) When there is a plurality of racks 10 of a user, whether or not dispersion installation may be performed is checked.

(2) Whether or not there is a non-allocable area for a rack 10 is checked.

(3) Whether the user is a new user or an existing user is checked.

(4) Whether or not the user rack 10 is a high load rack is checked.

(5) The allocation candidate racks 10 are narrowed down depending on the rack positions thereof.

(6) Continuous empty racks 10 are excluded from the allocation candidate racks 10.

(7) The rack 10 is allocated to a user system, and updating of the layout table 31c is instructed to the table managing unit 32.

In the operation (1), when the user racks 10 may be subjected to dispersion installation, the allocation unit 34 performs an allocation process with respect to an individual user rack 10. On the other hand, when the dispersion installation is not allowed, the allocation unit 34 performs the allocation process with reference to the “allocable area” in the layout table 31c so that continuous empty racks 10, as many as the number required by the allocation request, are allocated to the user (plurality of electronic instruments 10a).

When a plurality of racks 10 of the same user are subjected to dispersion installation and connected using LAN cables or the like between each of the racks 10, a wiring work becomes complicated since there also is wiring for racks 10 of other users between the racks 10 in the underfloor space 14. Therefore, the allocation unit 34 may make the wiring work easy by allocating racks 10 which are close to each other (preferably, neighboring racks) in response to the allocation request requiring racks 10 which are not allowed to be subjected to dispersion installation. Specifically, since there is a case in which many cables are laid between the racks 10 of the same user, such an allocation is effective when considering avoidance of congestion of the underfloor space 14.

In the operation (2), the allocation unit 34 refers to the “allocable area” in the layout table 31c. When there is a non-allocable area, the allocation unit 34 excludes racks 10 in the non-allocable area from the allocation candidate racks 10. The rack 10 which is excluded at this time is a rack 10 which is already allocated (the “propriety of allocation (presence or absence of user)” is “NG”), a rack 10 in a column of which the “underfloor height” is the “threshold value” or more (the “propriety of allocation (underfloor height)” is “NG”), and a rack 10 which faces a high load rack on the front face (the “high load” is “NG”).

For example, the allocation unit 34 excludes a rack 10 which faces a rack 10 which has a power consumption larger than a predetermined value (threshold value) from the allocation candidate racks 10 on which a new electronic instrument 10a is to be mounted. In other words, the allocation unit 34 is an example of a determination unit which determines a rack 10 which does not face a rack 10 which has power consumption larger than the predetermined value (threshold value) as an allocation candidate rack 10. In addition, the allocation unit 34 may determine, as a mounting destination candidate rack 10, a rack 10 to which a power supply line 12 which is laid in an underfloor space 13 which has the “underfloor height” less than the predetermined “threshold value” is connected.

In the operation (3), the allocation unit 34 refers to the “user name” in the layout table 31c, and checks whether the user involved in the allocation request is a new user or an existing user. A condition of narrowing down in the operation (5) of the allocation process is changed depending on whether the user is a new user or an existing user.

In the operation (4), the allocation unit 34 refers to allocation information input from the reception unit 33, and determines whether or not a rack power value of a user rack 10 is a predetermined value or more. When the power value is the predetermined threshold value or more, the allocation unit 34 determines that the user rack 10 is a high load rack, and when the power value is less than the predetermined threshold value, the allocation unit 34 determines that the user rack 10 is not the high load rack.

The allocation unit 34 may determine whether or not there is an empty rack 10 which is temporarily reserved with respect to the user by referring to the layout table 31c. When there is a temporarily reserved empty rack 10, the allocation unit 34 allocates the empty rack 10 to the user, and executes the operation (7) by skipping the procedures (5) and (6). At this time, it is preferable for the allocation unit 34 to temporarily reserve at least one empty rack 10 (for example, racks on both sides of the allocated empty rack 10) in the vicinity of the allocated empty rack 10 for the user. The allocation unit 34 may perform the temporary reservation when there are results in which the user has added a rack 10 within the past x years or y months (x and y are integers of 1 or more, respectively).

That is, when a rack 10 is determined as an allocation destination from among determined allocation candidate racks 10, the allocation unit 34 may make the temporary reservation with respect to a rack 10 neighboring the allocation destination rack 10 if the neighboring rack 10 is included in the allocation candidate racks 10. At this time, the allocation unit 34 may make the temporary reservation with respect to the rack 10 neighboring the allocation destination rack 10 as an allocation destination of another new electronic instrument 10a which is related to the allocation destination rack 10.

In the operation (5), when the user involved in the allocation request is a new user (refer to operation (3)), the allocation unit 34 determines allocation candidate racks 10 closer to the air conditioner 15 from among the allocation candidate racks 10. On the other hand, when the user involved in the allocation request is an existing user, the allocation unit 34 determines allocation candidate racks 10 closer to the rack 10 (existing rack 10 of the user) on which another electronic instrument 10a which is to be connected to the newly mounted electronic instrument 10a using a communication line (LAN, or the like) is mounted.

In this manner, the allocation unit 34 may efficiently use air conditioning ability by allocating a rack 10 which is closer to the air conditioner 15 to a new user. In addition, the allocation unit 34 may make a wiring work easy, and may avoid congestion of the underfloor space 14, similarly to the operation (1), by preferentially allocating a rack 10 which is closer to an existing rack 10 of an existing user in response to the allocation request.

In the operation (6), when there is a plurality of allocation candidate racks 10 after the narrowing down, the allocation unit 34 excludes continuous (neighboring) empty racks 10 from the allocation candidate racks 10. The reason for this is to preferentially allocate empty racks 10 which are close to each other to the plurality of racks 10, when dispersion installation of the plurality of racks 10 is not allowed in the operation (1).

In the operation (7), the allocation unit 34 allocates the allocation candidate racks 10 which is narrowed down to one or more racks to the user, and instructs the table managing unit 32 to update the layout table 31c. When there are many of allocation candidate racks 10 with respect to the rack 10 to be allocated, the allocation unit 34 selects, for example, racks 10 with names having smaller numbers from among the allocation candidate racks 10 to be allocated to the user. The updating of the layout table 31c is performed as follows by the table managing unit 32 upon receipt of the instruction from the allocation unit 34.

(i) “NG” is set to the “propriety of allocation (presence or absence of user)”, and the “allocable area” in the layout table 31c, respectively, with respect to the rack 10 which is allocated to the user, and the “user name” and the “start date” of the rack 10 are set. In addition, a power value which is included in the allocation information is set to the “rack power value (KVA)” in the layout table 31c.

(ii) When the allocated rack 10 is a high load rack (determination made in operation (4)), “NG” is set in the “high load”, and the “allocable area” in the layout table 31c, respectively, with respect to a rack 10 which faces the allocated rack 10 on the front face.

(iii) When the allocated rack 10 is a temporarily reserved rack, “YES” in the “temporary reservation” in the layout table 31c is replaced with “-” (for example, null) with respect to the allocated rack 10. When another empty rack 10 is temporarily reserved, “YES” is set in the “temporary reservation” in the layout table 31c with respect to the temporarily reserved rack 10.

(iv) An additional value corresponding to a distance between the allocated rack 10 and the distribution board 11 is obtained from the power supply line adding table 31b, and the “underfloor height” (cm) in the underfloor space value table 31a is updated with respect to the “power supply laying region” of the rack 10. When the “underfloor height” becomes the “threshold value” or more due to the updating of the “underfloor height”, “NG” is set in the “propriety of allocation” in the underfloor space value table 31a, and “NG” is set in the “propriety of allocation (underfloor height)” of all of corresponding racks 10 in the layout table 31c.

The allocation unit 34 may allocate an empty rack 10 to a user by executing the above described allocation process. The allocation unit 34 may cause the output unit 35 to output (for example, display) information related to a result (allocation candidate racks 10) of the allocation process.

The output unit 35 informs the operator of the result of the allocation process. For example, the output unit 35 may output the result of the allocation process to a display which displays the result of the allocation process which is informed by the allocation unit 34, or an output device such as a printer. The output unit 35 may inform the operator of the result of the allocation process using mail, or the like, or may store the result of the allocation process in a file. In this manner, the output unit 35 may identifiably output the allocation candidate racks 10 which is determined by the allocation unit 34, as the result of the allocation process.

The updating unit 36 obtains a power consumption value of each system of the distribution board 11 which is measured by the measuring unit 16. That is, the updating unit 36 is an example of an obtaining unit which obtains respective power consumption value with respect to the plurality of racks 10 which are installed in the server room 2 and on which electronic instruments 10a may be mounted.

The updating unit 36 compares the obtained power consumption value with a threshold value, and instructs the table managing unit 32 to update the “high load” in the layout table 31c with respect to a rack 10 which faces the rack 10 of the compared system on the front face.

The updating unit 36 compares the obtained power consumption value with the threshold value at a predetermined timing, for example, in each predetermined period, at a timing in which the power consumption value is changed by a predetermined value, a timing which is instructed by an operator, or the like. When the power consumption value is obtained from the measuring unit 16, the updating unit 36 may instruct the table managing unit 32 to set the obtained power consumption value to the corresponding “rack power value (KVA)” in the layout table 31c.

As an example, when the power consumption value of a rack 10 becomes a threshold value (3 KVA, for example) or more, the updating unit 36 instructs the table managing unit 32 to set “NG” to the “high load” in the layout table 31c with respect to a rack 10 which faces the high load rack 10 on the front face. Such a process is performed when an electronic instrument 10a is added on the rack 10.

As another example, when the power consumption value of a rack 10 becomes less than the threshold value (3 KVA, for example), the updating unit 36 instructs the table managing unit 32 to set “OK” to the “high load” in the layout table 31c with respect to a rack 10 which faces the low load rack 10 on the front face. Such a process is performed in a case in which an electronic instrument 10a is removed from the rack 10, a case in which the rack 10 itself (or all of electronic instruments 10a in rack 10) is removed, and providing of a service to a user is ended with respect to the rack 10, or the like.

When the power consumption value becomes 0, the updating unit 36 determines that providing of a service using the rack 10 is ended, and causes the table managing unit 32 to change a status of the rack 10 in the layout table 31c to an empty rack 10. For example, the table managing unit 32 clears (for example, setting to Null) the “user name”, the “start date”, and the “rack power value (KVA)” of the rack 10 in the layout table 31c, and sets “OK” to the “propriety of allocation (presence or absence of user)”.

In an underfloor additional value with respect to the rack 10 in the underfloor space value table 31a, an additional value which is added to the rack 10 by an operator or the like is subtracted after a removal work for the power supply lines 12 for the rack 10 involved in the service, of which providing is ended, by the operator for example. That is, the determination, by the updating unit 36, that providing of the service using the rack 10 is ended may trigger the removal work of the power supply line 12.

As described above, since the updating unit 36 may continuously monitor the power consumption value of each rack 10, it is possible to update the “allocable area” in the layout table 31c, without omission.

Therefore, according to the updating unit 36, it may be possible to avoid allocating, by mistake, a user rack 10 to a rack 10 which becomes a non-allocable area due to a high load, even when the operator does not recognize that a rack 10 which has been a low load rack when being received is changed to a high load rack due to an addition of an electronic instrument 10a, for example. In addition, even when the operator does not recognize that the rack 10 which has been a high load rack when being received is changed to a low load rack due to removal of an electronic instrument 10a, or completion of providing the service, for example, it may be possible to avoid an occurrence of a useless empty area (remaining area without being allocated even when it is in a low load circumstance).

The updating unit 36 may preserves hysteresis when determining high load or low load of a rack 10, and may use a first threshold value when determining that the rack becomes high load, and a second threshold value when determining that the rack becomes low load. At this time, it is preferable that the first threshold value is larger than the second threshold value. In this manner, it may be possible to avoid frequently changing the layout table 31c, due to a temporary increase and decrease in power consumption value of the rack 10, and to reduce a load of the managing unit 3.

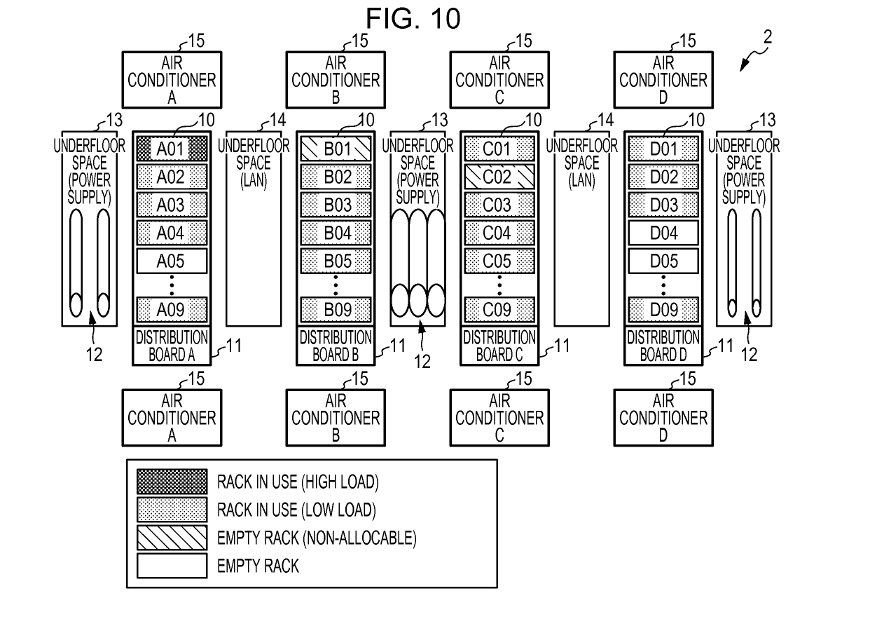

Subsequently, an exemplary operation when the allocation process performed by the managing unit 3 which is configured as described above is applied to allocation of an empty rack 10 in the server room 2 which is illustrated in FIG. 10 will be described. It is assumed that the managing unit 3 allocates one rack 10 with respect to a system with high load power of a new user.

For example, the allocation unit 34 checks that a user is a new user, and checks a non-allocable rack in a layout of the server room 2 with reference to the layout table 31c. As an example, as illustrated in FIG. 10, both the racks B01 and C02 are empty racks 10. However, the allocation unit 34 determines that these racks 10 are non-allocable racks.

The reason why the racks B01 and C02 are non-allocable racks is that the rack A01 which the B01 faces on the front face is already used and is a high load rack (the “high load” of the B01 is “NG”). The reason why the rack C02 is a non-allocable rack is that the “underfloor height” thereof is the “threshold value” or more, and the power supply cable of the underfloor space 13 is congested, that is, an empty space is not secured in the underfloor space 13 corresponding to the rack C02 (the “propriety of allocation (underfloor height)” of the C02 is “NG”).

Subsequently, the allocation unit 34 checks that the rack 10 to be allocated is a rack 10 with high load power, and the allocation candidate racks 10 (allocable racks) are narrowed down to empty racks 10 closer to the air conditioner 15. In addition, the allocation unit 34 excludes continuous empty racks 10 from the narrowed down allocation candidate racks 10. The allocation unit 34 allocates an empty rack 10 from among the narrowed down allocation candidate racks 10 to the user. At this time, when there is empty racks 10 which is at the same distance from the air conditioner 15, the allocation unit 34 allocates a rack 10 with a rack name having a smaller number to the user, for example.

In the example illustrated in FIG. 10, racks A05, D04, and D05 are allocation candidate racks 10 which are closer to the air conditioner 15. The allocation unit 34 leaves the continuous empty racks 10 (racks D04 and D05) among the allocation candidate racks 10 for an allocation process in which dispersion installation is not allowed, and allocates the rack A05 to the user.

Subsequently, the allocation unit 34 instructs the table managing unit 32 to update the underfloor space value table 31a. The table managing unit 32 refers to the power supply line adding table 31b, and obtains an additional value corresponding to a distance between the rack A05 (column A) and the distribution board 11. For example, when there is no empty breaker in the distribution boards A and B, the power supply line 12 is laid in the rack A05 from the distribution board C. In this case, the table managing unit 32 obtains 3 cm as an additional value when power is supplied between wall and column A from the distribution board C.

The table managing unit 32 adds 3 to the “underfloor height” between wall and column A in the underfloor space value table 31a, and determines whether or not the “underfloor height” after the addition is the “threshold value” or more. When the “underfloor height” is the “threshold value” or more, the table managing unit 32 changes racks 10 corresponding to the underfloor space between wall and column A to be non-allocable racks.

In addition, the table managing unit 32 may determine an additional value in consideration of a distance between a distribution board and a rack, as described above. For example, since a diameter of the power supply cable becomes 5 cm, as described above, when a distance between the distribution board C and the rack A05 is 10 m, the table managing unit 32 may add a value of 5 or less to the “underfloor height” between wall and column A in the underfloor space value table 31a.

In this manner, the allocation process for an empty rack 10 in the server room 2 with respect to a user which is illustrated in FIG. 10 is completed.

The above described managing unit 3 according to the present embodiment may automatically allocate a most suitable rack 10 from among empty rack spaces to a user by obtaining power consumption (number of power supply circuits) of each rack 10 in advance and using the underfloor space value table 31a. That is, it is possible to systemize the allocation process for the rack 10 with respect to a user by using allocation conditions in which priority is taken into consideration.

In addition, it is possible to grasp a load situation of each rack 10 according to an increase or decrease of electronic instruments 10a which is not recognized by an operator, and to instantly apply, to the allocation process, an exceptional condition such that a rack 10 which faces a high load rack 10 on the front face is non-allocable.

In this manner, according to the managing unit 3, it is possible to perform optimal rack allocation corresponding to each capacity in the server room 2. Thus, it is possible to efficiently use an air conditioning ability or a distribution board capacity in the server room 2, to obtain an energy saving effect due to a reduction in the number of operating air conditioners, or to reduce costs for adding distribution boards.

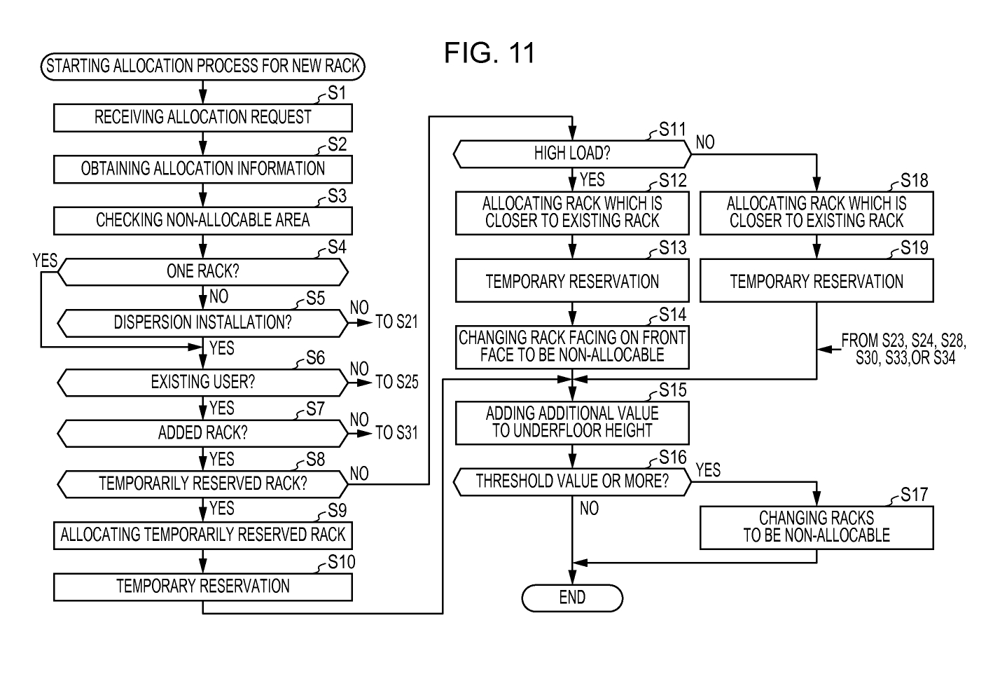

Subsequently, an exemplary operation of the managing unit 3 which is configured as described above will be described with reference to FIGS. 11 to 16.

First, an exemplary operation in the allocation process for new racks 10 performed by the managing unit 3 will be described with reference to the flowcharts illustrated in FIGS. 11 to 13.

As illustrated in FIG. 11, when receiving an allocation request from an operator (S1), the reception unit 33 obtains allocation information including installation specifications (power consumption value, or the like), the number of racks, propriety of dispersion installation, or the like (S2), and informs the allocation unit 34 of the allocation information.

The allocation unit 34 checks a non-allocable area with reference to the layout table 31c, (S3). The allocation unit 34 determines whether or not the number of allocation racks 10 to be allocated to a user is one on the basis of the obtained allocation information (S4), and when it is not one (No in S4), the allocation unit determines whether or not dispersion installation is possible (S5). When the dispersion installation is possible (Yes in S5), or when the number of the allocation racks 10 is one in S4 (Yes in S4), the allocation unit 34 determines whether or not the user is a new user (S6). This determination may be made, with reference to the layout table 31c, by determining whether or not there is a rack 10 having the “user name” indicating the user.

When the user is an existing user (Yes in S6), the allocation unit 34 determines whether or not there is a rack 10 which has been added within the past x years (S7). This determination may be made, with reference to the layout table 31c, by determining whether or not the “start date” of each existing rack 10 of the user is included within the past x years.

When there is a rack 10 which has been added within the past x years with respect to the existing user (Yes in S7), the allocation unit 34 determines whether or not there is a temporarily reserved rack 10 for the existing user (S8). When there is a temporarily reserved rack 10 (Yes in S8), the allocation unit 34 allocates the temporarily reserved rack 10 to the user (S9). The allocation unit 34 temporarily reserves both neighboring racks 10 of the allocated rack 10 (S10), and the process proceeds to S15.

On the other hand, when there is no temporarily reserved rack 10 in S8 (No in S8), the allocation unit 34 determines whether or not the allocation rack 10 is a high load rack (511). When the allocation rack 10 is a high load rack (Yes in S11), the allocation unit 34 allocates a rack 10 which is closer to the existing rack 10 to the user (S12), and temporarily reserves, for example, both neighboring racks 10 of the allocated rack 10 (S13).

In addition, the table managing unit 32 sets “NG” (non-allocable) to the “high load” and the “allocable area” in the layout table 31c, with respect to a rack 10 which faces the allocated rack 10 on the front face (S14).

Subsequently, the table managing unit 32 obtains an additional value corresponding to a distance between the allocated rack 10 (column) and the distribution board 11 from the power supply line adding table 31b, for example, and adds the additional value to the “underfloor height” in the underfloor space value table 31a (S15).

The table managing unit 32 determines whether or not the “underfloor height” is the “threshold value” or more (S16). When the “underfloor height” is less than the “threshold value” (No in S16), the process ends. On the other hand, when the “underfloor height” is the “threshold value” or more (Yes in S16), the table managing unit 32 changes racks 10 corresponding to the underfloor space to be non-allocable (S17), and the process ends.

On the other hand, when the allocation rack 10 is not a high load rack in S11 (No in S11), the allocation unit 34 allocates a rack 10 which is closer to the existing rack 10 to the user, similarly to S12 (S18), and temporarily reserves, for example, both neighboring racks 10 of the allocated rack 10 (S19), and the process proceeds to S15.

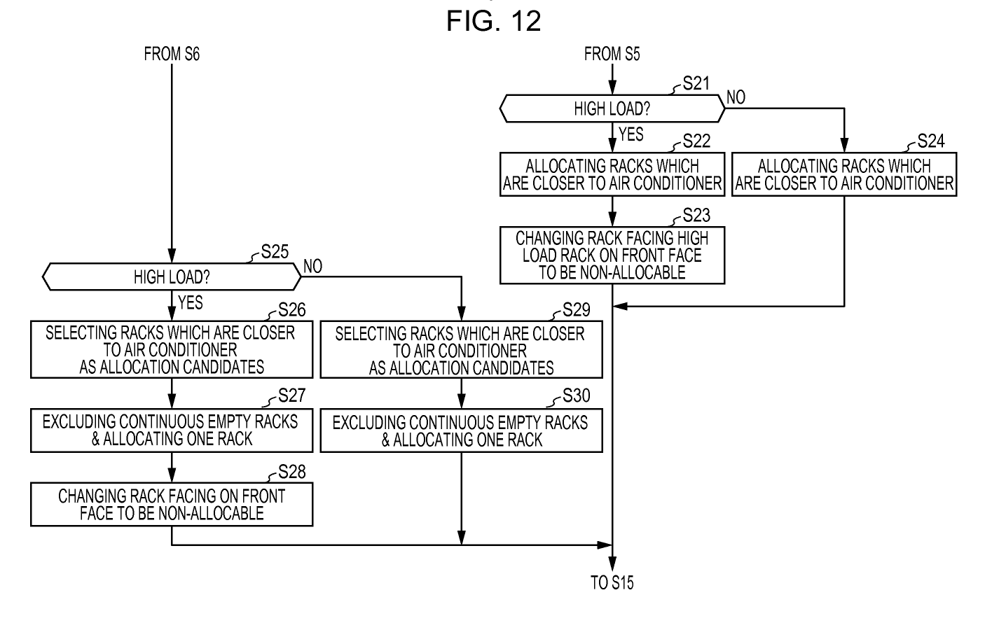

When dispersion installation is not allowed in S5 (No in S5), the process proceeds to S21 in FIG. 12. In S21, the allocation unit 34 determines whether or not each of the allocation racks 10 is a high load rack.

When at least one of the allocation racks 10 is a high load rack (Yes in S21), the allocation unit 34 allocates racks 10 which are closer to the air conditioner 15 to the user (S22). In addition, the table managing unit 32 sets “NG” (non-allocable) to the “high load” and the “allocable area” in the layout table 31c, with respect to a rack 10 which faces the high load rack 10 on the front face in the allocated racks 10 (S23), and the process proceeds to S15 in FIG. 11. In addition, when all of the allocation racks 10 are not high load racks in S21 (No in S21), the allocation unit 34 allocates racks 10 which are closer to the air conditioner 15 to the user (S24), and the process proceeds to S15 in FIG.

11

When the user is a new user in S6 (No in S6), the process proceeds to S25 in FIG. 12. In S25, the allocation unit 34 determines whether or not the allocation rack 10 is a high load rack.

When the allocation rack 10 is a high load rack (Yes in S25), the allocation unit 34 selects racks 10 which are closer to the air conditioner 15 as allocation candidate racks 10 (S26). The allocation unit 34 narrows down the allocation candidate racks 10 by excluding continuous empty racks 10, and allocates one rack 10 from the narrowed down allocation candidate racks 10 to the user (S27). In addition, the table managing unit 32 sets “NG” (non-allocable) to the “high load” and the “allocable area” in the layout table 31c, with respect to a rack 10 which faces the allocated rack 10 on the front face (S28), and the process proceeds to S15 in FIG. 11.

On the other hand, when the allocated rack 10 is not a high load rack in S25 (No in S25), the allocation unit 34 selects racks 10 which are closer to the air conditioner 15 as allocation candidate racks 10 (S29). The allocation unit 34 narrows down the allocation candidate racks 10 by excluding continuous empty racks 10 and allocates one rack 10 from the narrowed down allocation candidate racks 10 to the user (S30), and then the process proceeds to S15 in FIG. 11.

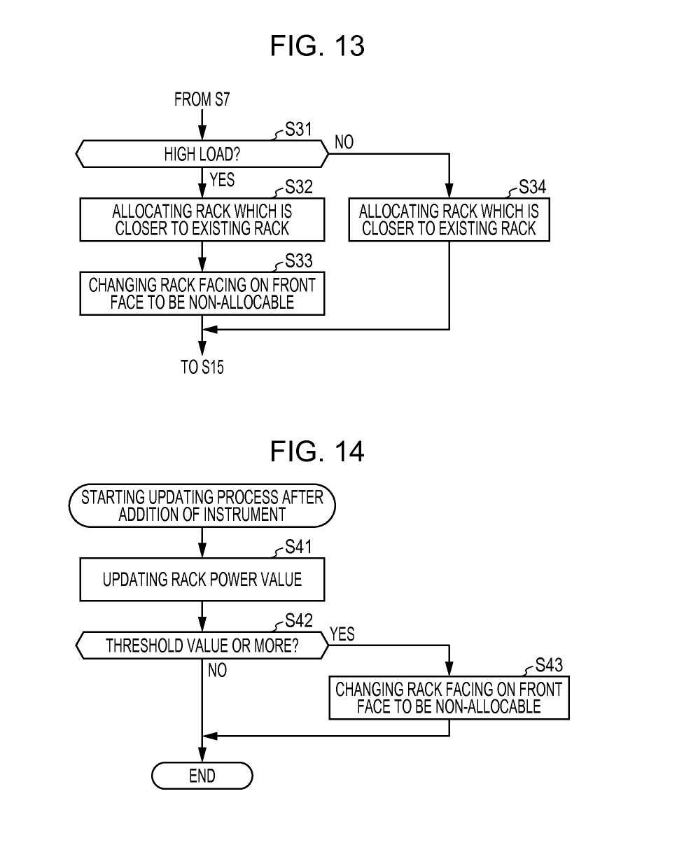

In S7, when there is no rack 10 which has been added within the past x years with respect to the existing user (No in S7), the process proceeds to S31 in FIG. 13. In S31, the allocation unit 34 determines whether or not the allocation rack 10 is a high load rack. When the allocation rack 10 is a high load rack (Yes in S31), the allocation unit 34 allocates a rack 10 which is closer to the existing rack 10 to the user (S32). In addition, the table managing unit 32 sets “NG” (non-allocable) to the “high load” and the “allocable area” in the layout table 31c, with respect to a rack 10 which faces the allocated rack 10 on the front face (S33), and the process proceeds to S15 in FIG. 11.

On the other hand, when the allocation rack 10 is not a high load rack in S31 (No in S31), the allocation unit 34 allocates a rack 10 which is closer to the existing rack 10 to the user (S34), and the process proceeds to S15 in FIG. 11.

The table managing unit 32 updates the layout table 31c, according to an instruction from the allocation unit 34 in S10, S13, S19, S22, S24, S27, S30, S32, S34, or the like. In the updating, information related to the “user name”, the “temporary reservation”, the “propriety of allocation”, and the like, is updated in the layout table 31c, with respect to the allocated rack 10.

Subsequently, an exemplary operation of an updating process after an addition of an electronic instrument 10a in an existing rack 10 by the managing unit 3 will be described with reference to the flowchart illustrated in FIG. 14.

Upon obtaining a power consumption value of each rack 10 from the measuring unit 16, the updating unit 36 updates the “rack power value (KVA)” in the layout table 31c, through the table managing unit 32 (S41), and determines whether or not the “rack power value (KVA)” is a threshold value or more (S42). When the “rack power value (KVA)” is less than the threshold value (No in S42), the process ends.

On the other hand, when the “rack power value (KVA)” is the threshold value or more in S42 (Yes in S42), the table managing unit 32 sets “NG” (non-allocable) to the “high load” and the “allocable area” in the layout table 31c, with respect to a rack 10 which faces the high load rack 10 on the front face (S43), and the process ends.

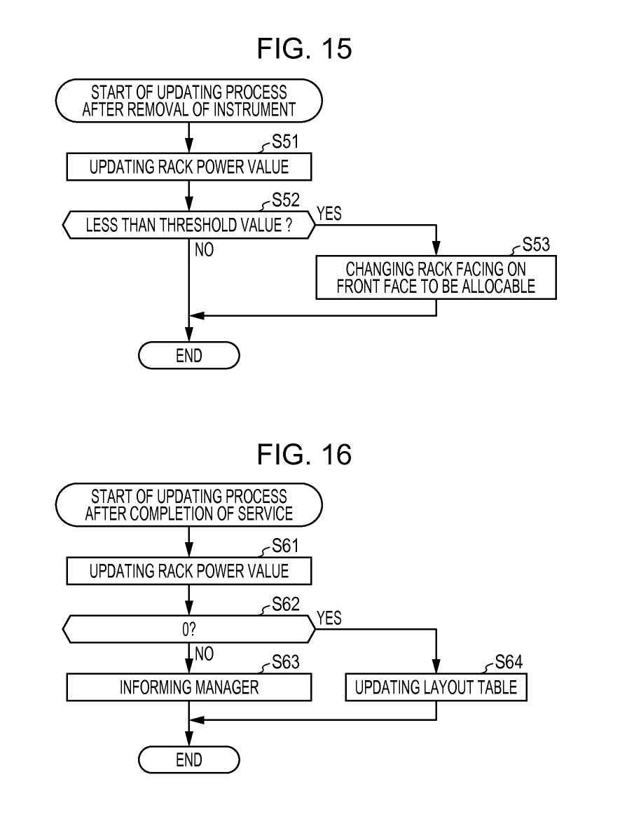

Subsequently, an exemplary operation of an updating process after removal of an electronic instrument 10a in an existing rack 10 by the managing unit 3 will be described with reference to the flowchart illustrated in FIG. 15.

Upon obtaining a power consumption value of each rack 10 from the measuring unit 16, the updating unit 36 updates the “rack power value (KVA)” in the layout table 31c, through the table managing unit 32 (S51), and determines whether or not the “rack power value (KVA)” is less than a threshold value (S52). When the “rack power value (KVA)” is the threshold value or more (No in S52), the process ends.

On the other hand, when the “rack power value (KVA)” is less than the threshold value (Yes in S52) in S52, the table managing unit 32 sets “OK” (allocable) to the “high load” and the “allocable area” in the layout table 31c, with respect to a rack 10 which faces the non-high load rack 10 on the front face (S53), and the process ends.

Subsequently, an exemplary operation of an updating process after completion of service in an existing rack 10 by the managing unit 3 will be described with reference to the flowchart illustrated in FIG. 16. The fact that the service is completed in each rack 10 may be stored in advance for the updating unit 36 by an operator or the like.

Upon obtaining a power consumption value of each rack 10 from the measuring unit 16, the updating unit 36 updates the “rack power value (KVA)” in the layout table 31c, through the table managing unit 32 (S61), and determines whether or not the “rack power value (KVA)” is 0 (S62). When the “rack power value (KVA)” is 0 (Yes in S62), the updating unit 36 determines that providing of service of the rack 10 is completed, and performs updating of the layout table 31c, through the table managing unit 32 (S64), and the process ends. In addition, when it is determined that providing of service of the rack 10 is completed, the updating unit 36 may inform an administrator (for example, operator) of the fact. The administrator who is informed of the fact may subtract an additional value which has been added for the rack 10 from an underfloor additional value with respect to the rack 10 in the underfloor space value table 31a, after the removal work for the power supply line 12 for the rack 10. In this manner, the administrator may perform maintenance of managing information in response to the completion of providing of service.

On the other hand, when the “rack power value (KVA)” is not 0 in S62 (No in S62), since there is a difference between information on completion of service which is stored and a comparison result, the updating unit 36 informs the administrator (for example, operator) (S63), and the process ends.

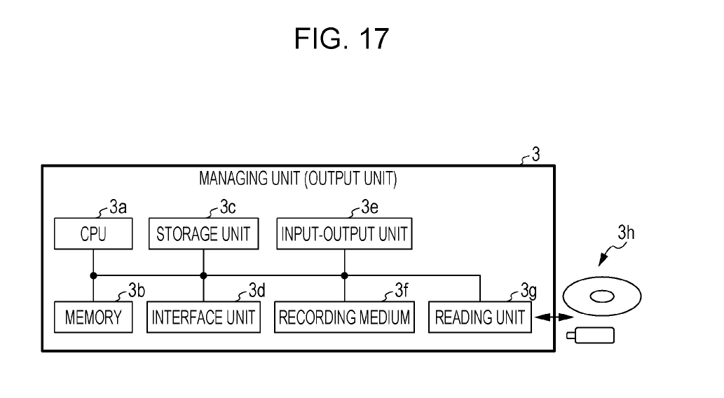

As illustrated in FIG. 17, the managing unit 3 includes a central processing unit (CPU) 3a, a memory 3b, a storage unit 3c, an interface unit 3d, an input-output unit 3e, a recording medium 3f, and a reading unit 3g.

The CPU 3a is an example of an arithmetic processing unit (processor) which performs various controls, or an operation. The CPU 3a is connected to each of corresponding components 3b to 3g, and may achieve various functions by executing a program which is stored in the memory 3b, the storage unit 3c, the recording medium 3f, a recording medium 3h, a read-only memory (ROM) which is not illustrated, or the like. For example, the CPU 3a may achieve functions of each of components 32 to 36 (refer to FIG. 5) of the managing unit 3, by executing an allocation program which is stored in the memory 3b.

The memory 3b is a memory unit which stores various data, or a program. When executing a program, the CPU 3a loads the program and data in the memory 3b. The memory 3b may store therein the allocation program. As the memory 3b, there is, for example, a volatile memory such as a random access memory (RAM). The storage unit 3c is hardware which stores various data, a program, or the like. As the storage unit 3c, there are various units of, for example, a magnetic disk unit such as an HDD, a semiconductor drive unit such as an SSD, and a non-volatile memory such as a flash memory. The storage unit 31 illustrated in FIG. 5 may be realized using at least one of the storage unit 3c and the memory 3b.

The interface unit 3d is a unit which performs a connection with the network 4 and another information processing device in a wired or wireless manner, and a control of communication. As the interface unit 3d, there is, for example, an adaptor which is compliant with a LAN, Fibre Channel (FC), InfiniBand, or the like. The input-output unit 3e may include at least one of an input unit such as a mouse, or a keyboard, and an output unit such as a display or a printer. For example, the input unit is used in operations such as various settings with respect to the managing unit 3 by an operator, or inputting of data (including allocation request), and the output unit is used when outputting an operation state, a processing result (result of allocation process), or the like, by the managing unit 3.

The recording medium 3f is a storage unit such as a flash memory, or a ROM, for example, and may record various data or a program. The reading unit 3g is a unit which reads data or a program which is recorded in the computer-readable recording medium 3h. An allocation program for achieving all or a part of various functions of the managing unit 3 according to the present embodiment may be stored at least one of the recording media 3f and 3h. For example, the CPU 3a may execute an allocation program which is read from the recording medium 3f, or an allocation program which is read from the recording medium 3h through the reading unit 3g by loading the program in a memory unit such as the memory 3b.

As the recording medium 3h, for example, there is a flexible disk, an optical disc such as a compact disc (CD), a digital versatile disc (DVD), and a Blu-ray disc, and a flash memory such as a universal serial bus (USB) memory and a secure digital (SD) card. As the CD, there is a CD-ROM, a CD-Recordable (CD-R), a CD-Rewritable (CD-RW), or the like. As the DVD, there is a DVD-ROM, a DVD-RAM, a DVD-R, a DVD-RW, a DVD+R, a DVD+RW, or the like.

Each of the above described components 3a to 3g is communicably connected with one another. The above described hardware configuration of the managing unit 3 is an example. Accordingly, an increase or decrease of hardware (for example, arbitrary addition or omission of component), a division, a unification through an arbitrary combination, an addition or omission of a bus, or the like, in the managing unit 3 may be arbitrarily performed.

### Other Embodiments

The first embodiment has been described above in detail. However, the disclosure is not limited to the specific embodiment, and may be executed by being variously modified or changed without departing from the scope of the disclosure.

For example, each functional component of the managing unit 3 which is illustrated in FIG. 5 may be merged by being arbitrarily combined, or may be divided.

The managing unit 3 according to the first embodiment determines a rack 10 to be allocated to a user from allocation candidate racks 10, and outputs the determined rack 10 to the output unit 35. However, there is no limitation to this. For example, the managing unit 3 may output information which specifies the narrowed down allocation candidate racks 10 to the output unit 35, and may prompt an operator to select a rack 10 to be allocated to a user from the output allocation candidate racks 10. In this case, the managing unit 3 may update the layout table 31c, with respect to the rack 10 which is selected by the operator.

the managing unit 3 according to the first embodiment sets a rack 10 which faces a high load rack on the front face to be a non-allocable rack, by assuming that the rack 10 (electronic instrument 10a) takes in air on the front face, and exhaust air on the rear face. However, there is no limitation to this. When the intake side and the exhaust side of the rack 10 (electronic instrument 10a) are different from those in the above description, the managing unit 3 may set a rack 10 which faces the high load rack on the intake side to be a non-allocable rack.

The managing unit 3 according to the first embodiment manages an underfloor space value with respect to the underfloor space 13 in which the power supply line 12 is laid. However, there is no limitation to this, and an underfloor space value of the underfloor space 14 may also be managed, similarly. In addition, the managing unit 3 may manage a space value with respect to various spaces which are arbitrary spaces through which cold air passes, and in which a cable or an installed object is present without being limited to the underfloor space.

In the above description, a power value (KVA) such as a rack power value, and a power consumption value are used as information denoting power (power consumption). However, there is no limitation to this, and electric energy (KWh) may be used instead of the power value (KVA). When a power value and electric energy are mixed, the power value may be converted into electric energy by multiplying the power value by unit time (1 hour), or the electric energy may be converted into a power value by dividing the electric energy by unit time (1 hour). In addition, the electric energy (KWh) may be used instead of the power value (KVA) with respect to each threshold value which is used when determining a high load of a rack 10 by the allocation unit 34, determining removal or addition of the electronic instrument 10a by the updating unit 36, determining completion of service of a rack 10 by the updating unit 36, or the like.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A computer-readable recording medium having stored therein a program that causes a computer to execute a process, the process comprising:
obtaining respective power consumption values of a plurality of housings installed in a room;
determining, on basis of the obtained power consumption values, first housings each have a power consumption value larger than a predetermined value;
selecting, as mounting destination candidates for a mounting destination of a first electronic apparatus to be installed in the room, second housings each of which accommodates the first electronic apparatus and faces none of the first housings from the plurality of housings on basis of arrangement information indicating arrangement of the plurality of housings in the room; and
outputting information regarding at least one of the mounting destination candidates.

2. The computer-readable recording medium according to claim 1, wherein
the plurality of housings are arranged in a plurality of columns,
the room is provided, corresponding to the respective columns, with ventilation spaces through which cooling air for cooling the housings forming the respective columns passes and in which cables connected to the housings forming the respective columns are laid, and
the process further comprises:
managing space values which indicate spaces occupied by the cables in the respective ventilation spaces; and
narrowing down the mounting destination candidates to the housings connected to the cables laid in the ventilation spaces having the space values less than a predetermined threshold value.

3. The computer-readable recording medium according to claim 1, the process further comprising:
determining a third housing for the first electronic apparatus from among the mounting destination candidates, the third housing being installed closer to any of air conditioners for cooling the plurality of housings.

4. The computer-readable recording medium according to claim 1, the process further comprising:
determining a third housing for the first electronic apparatus from among the mounting destination candidates, the third housing being installed closer to a fourth housing on which a second electronic apparatus is mounted, the second electronic apparatus being to be connected to the first electronic apparatus through a communication line.

5. The computer-readable recording medium according to claim 1, the process further comprising:
narrowing down the mounting destination candidates by excluding the housings neighboring each other.

6. The computer-readable recording medium according to claim 1, the process further comprising:
determining neighboring housings from among the mounting destination candidates when a plurality of electronic apparatuses are to be mounted on a plurality of housings.

7. The computer-readable recording medium according to claim 1, the process further comprising:
determining a third housing for the first electronic apparatus from among the mounting destination candidates; and
temporarily reserving, when a fourth housing neighboring the third housing is included in the mounting destination candidates, the fourth housing as a mounting destination of a second electronic apparatus to be installed in the room, the second electronic apparatus being related to the third housing.

8. A housing allocation device, comprising:
a processor configured to
obtain respective power consumption values of a plurality of housings installed in a room;
determine, on basis of the obtained power consumption values, first housings each have a power consumption value larger than a predetermined value;
select, as mounting destination candidates for a mounting destination of a first electronic apparatus to be installed in the room, second housings each of which accommodates the first electronic apparatus and faces none of the first housings from the plurality of housings on basis of arrangement information indicating arrangement of the plurality of housings in the room; and
output information regarding at least one of the mounting destination candidates.

9. The housing allocation device according to claim 8, wherein
the plurality of housings are arranged in a plurality of columns,
the room is provided, corresponding to the respective columns, with ventilation spaces through which cooling air for cooling the housings forming the respective columns passes and in which cables connected to the housings forming the respective columns are laid, and
the process is further configured to
manage space values which indicate spaces occupied by the cables in the respective ventilation spaces; and
narrow down the mounting destination candidates to the housings connected to the cables laid in the ventilation spaces having the space values less than a predetermined threshold value.

10. The housing allocation device according to claim 8, wherein the process is further configured to
determine a third housing for the first electronic apparatus from among the mounting destination candidates, the third housing being installed closer to any of air conditioners for cooling the plurality of housings.

11. The housing allocation device according to claim 8, wherein the process is further configured to
determine a third housing for the first electronic apparatus from among the mounting destination candidates, the third housing being installed closer to a fourth housing on which a second electronic apparatus is mounted, the second electronic apparatus being to be connected to the first electronic apparatus through a communication line.

12. The housing allocation device according to claim 8, wherein the process is further configured to
narrow down the mounting destination candidates by excluding the housings neighboring each other.

13. The housing allocation device according to claim 8, wherein the process is further configured to
determine neighboring housings from among the mounting destination candidates when a plurality of electronic apparatuses are to be mounted on a plurality of housings.

14. The housing allocation device according to claim 8, wherein the process is further configured to
determine a third housing for the first electronic apparatus from among the mounting destination candidates; and
temporarily reserve, when a fourth housing neighboring the third housing is included in the mounting destination candidates, the fourth housing as a mounting destination of a second electronic apparatus to be installed in the room, the second electronic apparatus being related to the third housing.

15. A method for allocating a housing, the method comprising:
obtaining, by a computer, respective power consumption values of a plurality of housings installed in a room;
determining, on basis of the obtained power consumption values, first housings each have a power consumption value larger than a predetermined value;
selecting, as mounting destination candidates for a mounting destination of a first electronic apparatus to be installed in the room, second housings each of which accommodates the first electronic apparatus and faces none of the first housings from the plurality of housings on basis of arrangement information indicating arrangement of the plurality of housings in the room; and
outputting information regarding at least one of the mounting destination candidates.

16. The method according to claim 15, wherein
the plurality of housings are arranged in a plurality of columns,
the room is provided, corresponding to the respective columns, with ventilation spaces through which cooling air for cooling the housings forming the respective columns passes and in which cables connected to the housings forming the respective columns are laid, and
the method further comprises:
managing space values which indicate spaces occupied by the cables in the respective ventilation spaces; and
narrowing down the mounting destination candidates to the housings connected to the cables laid in the ventilation spaces having the space values less than a predetermined threshold value.

17. The method according to claim 15, the method further comprising:
determining a third housing for the first electronic apparatus from among the mounting destination candidates, the third housing being installed closer to any of air conditioners for cooling the plurality of housings.

18. The method according to claim 15, the method further comprising:
determining a third housing for the first electronic apparatus from among the mounting destination candidates, the third housing being installed closer to a fourth housing on which a second electronic apparatus is mounted, the second electronic apparatus being to be connected to the first electronic apparatus through a communication line.

19. The method according to claim 15, the method further comprising:
narrowing down the mounting destination candidates by excluding the housings neighboring each other.

20. The method according to claim 15, the method further comprising:
determining a third housing for the first electronic apparatus from among the mounting destination candidates; and
temporarily reserving, when a fourth housing neighboring the third housing is included in the mounting destination candidates, the fourth housing as a mounting destination of a second electronic apparatus to be installed in the room, the second electronic apparatus being related to the third housing.
